(19) United States
(12) Patent Application Publication
(10) Pub. No.: US 2024/0244938 A1
(43) Pub. Date: Jul. 18, 2024

(54) DISPLAY DEVICE

(71) Applicant: InnoLux Corporation, Miao-Li County (TW)

(72) Inventors: Wen-Tse LI, Miao-Li County (TW); Shih-Fu LIAO, Miao-Li County (TW); I-An YAO, Miao-Li County (TW)

(21) Appl. No.: 18/539,817

(22) Filed: Dec. 14, 2023

(30) Foreign Application Priority Data
Jan. 13, 2023 (CN) 202310039158.9

(51) Int. Cl. H10K 59/80

(52) U.S. Cl. CPC H10K 59/879; H10K 59/8792

(57) ABSTRACT

A display device includes a first substrate, a light emitting unit and a first micro lens unit. The light emitting unit is arranged on the first substrate to provide a light. The first micro lens unit is arranged on the light emitting unit to adjust the traveling direction of the light, wherein there is a distance from the light emitting surface of the light emitting unit to a position of half the height of the first micro lens unit, the first micro lens unit has an arc surface, the first micro lens unit has a height, and the arc surface has a curvature radius, and the distance and the curvature radius satisfy the relationship: 0.5H≤D≤3R1, where D represents the distance, H represents the height, and R1 represents the curvature radius.

### CROSS-REFERENCE TO RELATED APPLICATIONS

This application claims the benefits of the Chinese Patent Application Serial Number 202310039158.9, filed on Jan. 13, 2023, the subject matter of which is incorporated herein by reference.

### BACKGROUND

### Field of the Disclosure

The present disclosure relates to a display device and, more specifically, to a light emitting diode display device.

### Description of Related Art

When the existing light emitting diode display device performs displaying, the light emitted by the light emitting diode (LED) will enter the medium with a relatively small refractive index from the medium with a relatively large refractive index. Due to the refraction, the light is dispersed and, when in severe cases, it will be limited by the critical angle of total reflection, and the light with a large angle is reflected and cannot be emitted, resulting in greatly reducing the efficiency of light emitting.

Therefore, it is desired to provide an improved display device to mitigate and/or obviate the aforementioned problems.

### SUMMARY

The present disclosure provides a display device, which can concentrate the light emitted by the light emitting diode within the critical angle, thereby improving the light emitting efficiency.

In one aspect of the present disclosure, the display device includes: a first substrate; a light emitting unit arranged on the first substrate to provide a light; and a first micro lens unit arranged on the light emitting unit to adjust a traveling direction of the light, wherein the first micro lens unit has an arc surface, the first micro lens unit has a height, the arc surface has a curvature radius, there is a distance from a light emitting surface of the light emitting unit to a position of half the height of the first micro lens unit, and the distance and the curvature radius satisfy: 0.5H≤D≤3R1, where D represents the distance, H represents the height, and R1 represents the curvature radius.

In another aspect of the present disclosure, the display device includes: a first substrate; a light emitting unit arranged on the first substrate to provide a light; a color filter unit arranged on the light emitting unit; and an intermediary layer arranged between the color filter unit and the light emitting unit and surrounding the light emitting unit, wherein there is a pixel define layer between the light emitting unit and another adjacent light emitting unit, and a material of the pixel define layer is a highly reflective material.

Other novel features of the disclosure will become more apparent from the following detailed description when taken in conjunction with the accompanying drawings.

### BRIEF DESCRIPTION OF DRAWINGS

FIG. 1 is a schematic diagram of a display device according to an embodiment of the present disclosure;

FIG. 2 is a schematic diagram of a display device according to an embodiment of the present disclosure;

FIG. 3 is a schematic diagram of a display device according to an embodiment of the present disclosure;

FIG. 4 is a schematic diagram of a display device according to an embodiment of the present disclosure;

FIG. 5 is a schematic diagram of a display device according to an embodiment of the present disclosure;

FIG. 6 is a schematic diagram of a display device according to an embodiment of the present disclosure;

FIG. 7 is a schematic diagram of a display device according to an embodiment of the present disclosure;

FIG. 8 is a schematic diagram of a display device according to an embodiment of the present disclosure;

FIG. 9A shows the configuration relationship of the first micro lens unit by taking the display device of FIG. 4 as an example;

FIG. 9B shows the configuration relationship of the first micro lens unit by taking the display device of FIG. 6 as an example;

FIG. 10 shows the configuration relationship of the micro lens units by taking the display device of FIG. 7 as an example;

FIG. 11 is a schematic diagram of a display device according to an embodiment of the present disclosure;

FIG. 12 is a schematic diagram of a display device according to an embodiment of the present disclosure;

FIG. 13 is a schematic diagram of a display device according to an embodiment of the present disclosure;

FIG. 14 is a schematic diagram of a display device according to an embodiment of the present disclosure;

FIG. 15 is a schematic diagram of a display device according to an embodiment of the present disclosure;

FIG. 16 shows the configuration relationship of the first micro lens unit by taking the display device of FIG. 14 as an example;

FIG. 17 shows the configuration relationship of the first micro lens unit by taking the display device of FIG. 15 as an example; and

FIG. 18 is a schematic diagram of a display device according to an embodiment of the present disclosure.

### DETAILED DESCRIPTION OF EMBODIMENT

Different embodiments of the present disclosure are provided in the following description. These embodiments are meant to explain the technical content of the present disclosure, but not meant to limit the scope of the present disclosure. A feature described in an embodiment may be applied to other embodiments by suitable modification, substitution, combination, or separation.

It should be noted that, in the present specification, when a component is described to “comprise”, “have”, “include” an element, it means that the component may include one or more of the elements, and the component may include other elements at the same time, and it does not mean that the component has only one of the element, except otherwise specified.

Moreover, in the present specification, the ordinal numbers, such as “first” or “second”, are only used to distinguish a plurality of elements having the same name, and it does not means that there is essentially a level, a rank, an executing order, or an manufacturing order among the elements, except otherwise specified. The ordinal numbers of the elements in the specification may not be the same in claims. For example, a “second” element in the specification may be a “first” element in the claims.

In the present specification, except otherwise specified, the feature A “or” or “and/or” the feature B means only the existence of the feature A, only the existence of the feature B, or the existence of both the features A and B. The feature A “and” the feature B means the existence of both the features A and B.

Moreover, in the present specification, the terms, such as “top”, “upper”, “bottom”, “front”, “back”, or “middle”, as well as the terms, such as “on”, “above”, “over”, “under”, “below”, or “between”, are used to describe the relative positions among a plurality of elements, and the described relative positions may be interpreted to include their translation, rotation, or reflection.

Furthermore, the terms recited in the specification and the claims such as “above”, “over”, “on”, “below”, or “under” are intended that an element may not only directly contacts other element, but also indirectly contact the other element.

Furthermore, the term recited in the specification and the claims such as “connect” is intended that an element may not only directly connect to other element, but also indirectly connect to other element. On the other hand, the terms recited in the specification and the claims such as “electrically connect” and “couple” are intended that an element may not only directly electrically connect to other element, but also indirectly electrically connect to other element.

In the present specification, except otherwise specified, the terms (including technical and scientific terms) used herein have the meanings generally known by a person skilled in the art. It should be noted that, except otherwise specified in the embodiments of the present disclosure, these terms (for example, the terms defined in the generally used dictionary) should have the meanings identical to those skilled in the art, the background of the present disclosure or the context of the present specification, and should not be read by an ideal or over-formal way.

The light emitting unit of the present disclosure may, for example, include an organic light emitting diode (OLED), a sub-millimeter light emitting diode (mini LED), a micro light emitting diode (micro LED), a quantum dot light emitting diode (quantum dot LED) or other suitable materials, or a combination thereof, but it is not limited thereto. The display device may include, for example, a tiled display device, but it is not limited thereto.

FIG. 1 is a schematic diagram of a display device according to an embodiment of the present disclosure. The display device includes a first substrate 101, at least one light emitting unit 103 and at least one first micro lens unit 105. In this embodiment, the at least one light emitting unit 103 includes a red light emitting diode RLED, a green light emitting diode GLED and a blue light emitting diode BLED to provide red light, green light and blue light, respectively. The at least one first micro lens unit 105 includes a first micro lens unit 1051, a first micro lens unit 1052, and a first micro lens unit 1053 corresponding to the red light emitting diode RLED, the green light emitting diode GLED, and the blue light emitting diode BLED. It is noted that the type and quantity of the aforementioned light emitting units 103 and the first micro lens units 105 are only examples for convenience of description, and the present invention is not limited thereto. For example, when the display device is a quantum dot (QD) display device, the light emitting units 103 are all blue light emitting diodes BLED. The aforementioned red light emitting diode RLED, green light emitting diode GLED and blue light emitting diode BLED and the corresponding first micro lens unit 1051, first micro lens unit 1052 and first micro lens unit 1053 may constitute a display pixel of display device, and the display device has a plurality of display pixels to provide the display function, wherein, in this embodiment, a display pixel includes a red sub-pixel (formed by the red light emitting diode RLED and the corresponding first micro lens unit 1051), a green sub-pixel (formed by the green light emitting diode GLED and the corresponding first micro lens unit 1052), and a blue sub-pixel (formed by the blue light emitting diode BLED and the corresponding first micro lens unit 1053), but the present disclosure is not limited thereto.

The aforementioned light emitting unit 103 is arranged on the first substrate 101 to provide a light. In more detail, the aforementioned red light emitting diode RLED, green light emitting diode GLED and blue light emitting diode BLED are arranged on the first substrate 101, and there is a pixel define layer PDL between two adjacent light emitting units 103 to separate different light emitting units 103. The aforementioned first micro lens unit 105 is disposed on the light emitting unit 103 to adjust the traveling direction of the light provided by the light emitting unit 103. More specifically, the first micro lens unit 105 has an arc surface, and the first micro lens unit 105 is arranged on the first substrate 101 such that the arc surface is an outwardly convex arc surface facing away from the light emitting unit 103. The first micro lens unit 105 has a refractive index satisfying the relationship: 1.0≤n2<n1≤2.0, where n1 is the refractive index of the first micro lens unit 105, and n2 is the refractive index of the medium outside the first micro lens unit 105. Specifically, the material of the first micro lens unit 105 includes organic substances such as polymers and resins, for example, photoresist, but it is not limited thereto. In more detail, the first micro lens unit 1051, the first micro lens unit 1052 and the first micro lens unit 1053 are respectively arranged on the red light emitting diode RLED, the green light emitting diode GLED and the blue light emitting diode BLED to adjust the traveling direction of red light, green light and blue light according to the aforementioned relationship of refractive index, so that the light converges and does not reflect, thereby improving the light emitting efficiency.

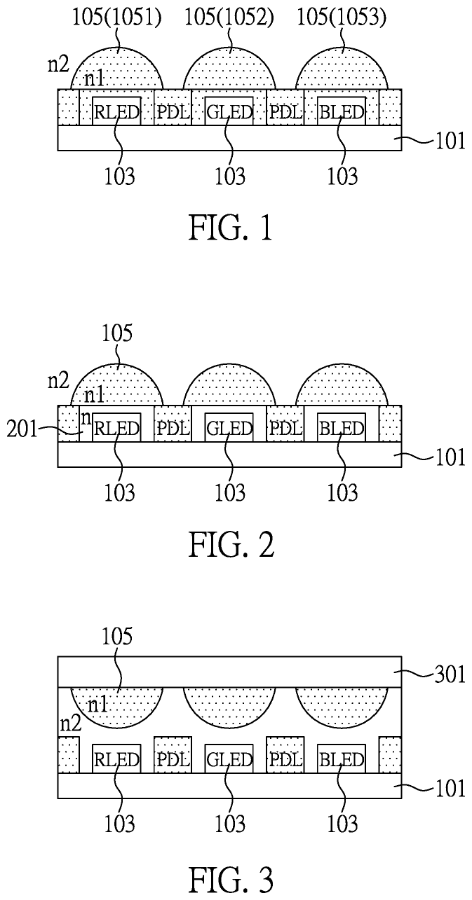

FIG. 2 is a schematic diagram of a display device according to an embodiment of the present disclosure. The display device of this embodiment is similar to the embodiment of FIG. 1, except that it further includes an intermediary layer 201. The intermediary layer 201 is disposed between the first micro lens unit 105 and the light emitting unit 103 and surrounds the light emitting unit 103, and the refractive index of the intermediary layer 201 is smaller than the refractive index of the first micro lens unit 105. More specifically, the refractive index of the intermediary layer 201 satisfies the relationship: 1.0≤n, n2<n1≤2.0, where n is the refractive index of the intermediary layer, n1 is the refractive index of the first micro lens unit 105, and n2 is the refractive index of the medium outside the first micro lens unit 105.

FIG. 3 is a schematic diagram of a display device according to an embodiment of the present disclosure. The display device of this embodiment is similar to the embodiment of FIG. 2, except that it further includes a second substrate 301 arranged to be opposite to the first substrate 101, and the first micro lens unit 105 is disposed on the second substrate 301. The first micro lens unit 105 has an arc surface, which is an outwardly convex arc surface facing the light emitting unit 103, and the refractive index of the first micro lens unit 105 satisfies the relationship: 1.0≤n2<n1≤2.0, where n1 is the refractive index of the first micro lens unit 105, and n2 is the refractive index of the medium between the first micro lens unit 105 and the light emitting unit 103.

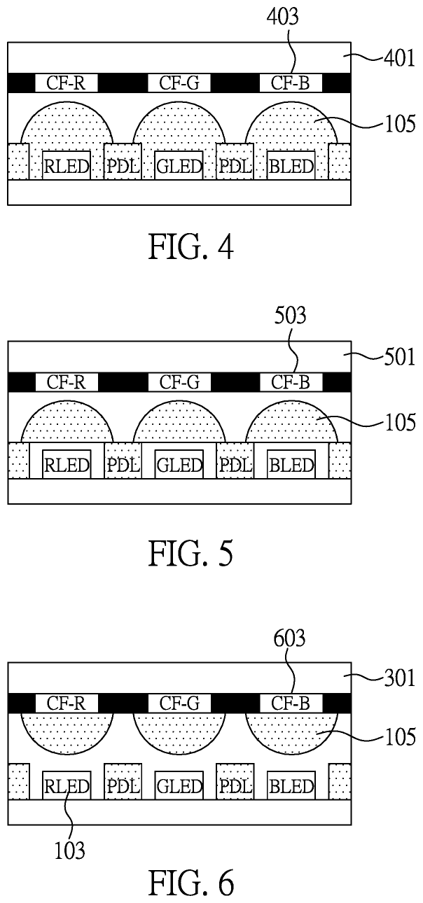

FIG. 4 is a schematic diagram of a display device according to an embodiment of the present disclosure. The display device of this embodiment is similar to the embodiment of FIG. 1, except that it further includes a second substrate 401 and at least one color filter unit 403. In this embodiment, in more detail, the at least one color filter unit 403 includes a red filter unit CF-R, a green filter unit CF-G and a blue filter unit CF-B, wherein a black matrix (BM) layer, as denoted by dark black segment, is included between the red filter unit CF-R and the green filter unit CF-G, and a black matrix (BM) layer is included between the green filter unit CF-G and the blue filter unit CF-B, which are respectively corresponding to the red light emitting diode RLED, the green light emitting diode GLED and the blue light emitting diode BLED, but this is just for illustrative purpose and the present disclosure is not limited thereto. Furthermore, the color filter unit 403 is disposed between the first micro lens unit 105 and the second substrate 401, and the arc surface of the first micro lens unit 105 is an outwardly convex arc surface facing the color filter unit 403.

FIG. 5 is a schematic diagram of a display device according to an embodiment of the present disclosure. The display device of this embodiment is similar to the embodiment of FIG. 2, except that it further includes a second substrate 501 and at least one color filter unit 503. In this embodiment, in more detail, the at least one color filter unit 503 includes a red filter unit CF-R, a green filter unit CF-G and a blue filter unit CF-B, which respectively correspond to the red light emitting diode RLED, the green light emitting diode GLED and the blue light emitting diode BLED, but this is just for illustrative purpose, and the present disclosure is not limited thereto. Moreover, the color filter unit 503 is disposed between the first micro lens unit 105 and the second substrate 501, and the arc surface of the first micro lens unit 105 is an outwardly convex arc surface facing the color filter unit 503.

FIG. 6 is a schematic diagram of a display device according to an embodiment of the present disclosure. The display device of this embodiment is similar to the embodiment of FIG. 3, except that it further includes at least one color filter unit 603 arranged between the first micro lens unit 105 and the second substrate 301. In this embodiment, in more detail, the at least one color filter unit 603 includes a red filter unit CF-R, a green filter unit CF-G and a blue filter unit CF-B respectively corresponding to the red light emitting diode RLED, the green light emitting diode GLED and the blue light emitting diode BLED, but this is just for illustrative purpose and the present disclosure is not limited thereto. Furthermore, the arc surface of the first micro lens unit 105 is an outwardly convex arc surface facing the light emitting unit 103.

FIG. 7 is a schematic diagram of a display device according to an embodiment of the present disclosure. The display device of this embodiment is similar to the embodiment of FIG. 4, except that it further includes at least one second micro lens unit 705 arranged between the first micro lens unit 105 and the color filter unit 403. In this embodiment, correspondingly, the at least one second micro lens unit 705 includes a second micro lens unit 7051, a second micro lens unit 7052 and a second micro lens unit 7053, which respectively correspond to the red light emitting diode RLED, the green light emitting diode GLED and the blue light emitting diode BLED. Furthermore, the arc surface of the first micro lens unit 105 is an outwardly convex arc surface facing the color filter unit 403, while the second micro lens unit 705 has another arc surface, which is an outer convex arc surface facing the light emitting unit 103, and the width of the first micro lens unit 105 is greater than the width of the second micro lens unit 705.

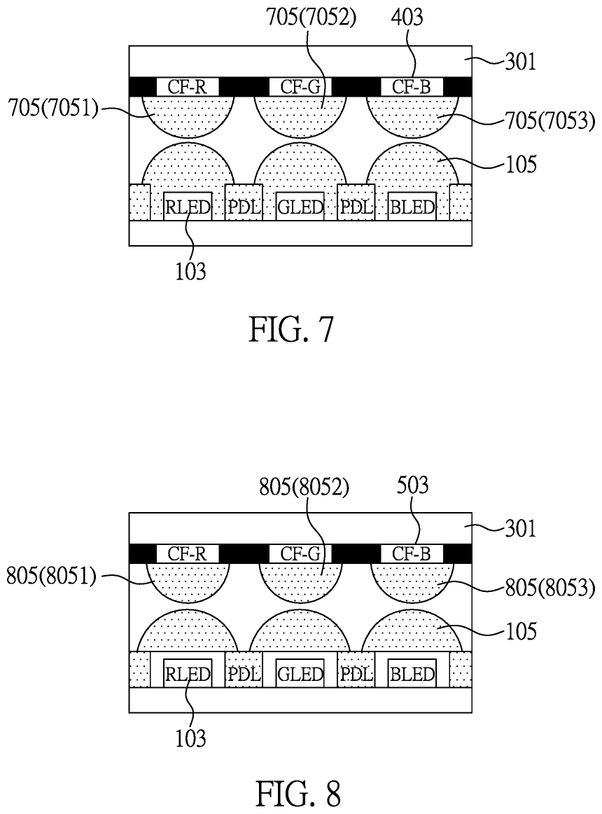

FIG. 8 is a schematic diagram of a display device according to an embodiment of the present disclosure. The display device of this embodiment is similar to the embodiment of FIG. 5, except that it further includes at least one second micro lens unit 805 arranged between the first micro lens unit 105 and the color filter unit 503. In this embodiment, correspondingly, the at least one second micro lens unit 805 includes a second micro lens unit 8051, a second micro lens unit 8052 and a second micro lens unit 8053, which respectively correspond to the red light emitting diode RLED, the green light emitting diode GLED and the blue light emitting diode BLED. Furthermore, the arc surface of the first micro lens unit 105 is an outwardly convex arc surface facing the color filter unit 503, while the second micro lens unit 805 has another arc surface, which is an outwardly convex arc surface facing the light emitting unit 103, and the width of the first micro lens unit 105 is greater than the width of the second micro lens unit 805.

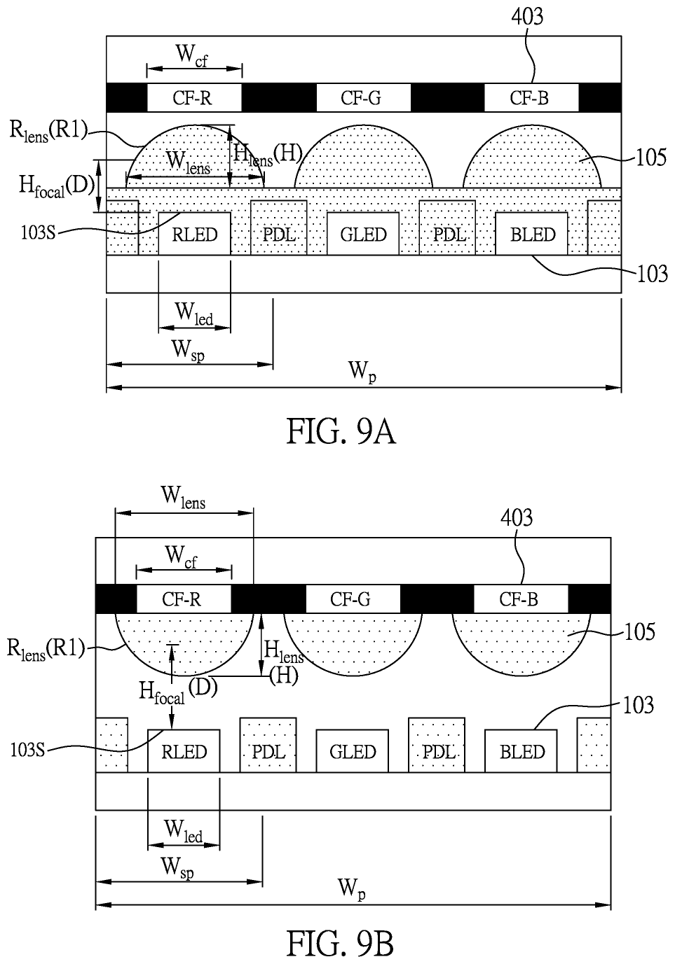

The aforementioned embodiments of the present disclosure are provided to avoid total reflection by arranging the micro lens unit in the display device to improve light emitting efficiency. To illustrate the configuration for achieving high light emitting efficiency, please refer to FIG. 9A and FIG. 9B, which illustrate the configuration relationship of the micro lens unit by respectively taking the display devices of FIG. 4 and FIG. 6 as examples. In FIG. 9A and FIG. 9B, there is a distance D from the light emitting surface 103S of the light emitting unit 103 to a position of half the height of the first micro lens unit 105D (marked as H_{focal} in FIG. 9A and FIG. 9B), the arc surface of the first micro lens unit 105 has a curvature radius R1 (marked as Rₗₑₙₛ in FIG. 9A and FIG. 9B), and the first micro lens unit 105 has a height H (marked as Hₗₑₙₛ in FIG. 9A and FIG. 9B), wherein the distance D and the curvature radius R1 satisfy the relationship: 0.5H≤D≤3R1, which may concentrate the large-angle light emitted by the light emitting diode so as to make the light limited within the critical angle, thereby improving the light emitting efficiency.

In more detail, in FIG. 9A and FIG. 9B, various components of the display pixel of the display device need to satisfy the following relationship:

$${W}_{sp} \geq {W}_{lens} ,$$

$${W}_{cf} \geq {W}_{led} ,$$

$${H}_{lens} \leq 1 / 2 {W}_{lens} ,$$

$${H}_{focal} \leq 3 {R}_{lens} ;$$

$$and$$

$$1 / 3 {W}_{p} = {W}_{sp} ,$$

where Wₛₚ represents the width of the sub-pixel, Wₗₑₙₛ represents the width of the first micro lens unit 105, which may be defined as the width of the bottom of the first micro lens unit, Hₗₑₙₛ represents the height of the first micro lens unit 105, which may be defined as the distance from the bottom to the top of the first micro lens unit 105, Rₗₑₙₛ represents the curvature radius of the first micro lens unit 105, W_{cf} represents the width of the color filter unit 403, which may be defined as the maximum width of the color filter unit 403, W_{led} represents the width of the light emitting unit 103, which may be defined as the maximum width of the light emitting unit, H_{focal} represents the distance between the light emitting surface 103S of the light emitting unit 103 and the position of half the height of the first micro lens unit 105, and Wₚ represents the width of the display pixel, which may be defined as the distance value measured between the center of the light emitting diode RLED and the center of the close light emitting diode RLED under a cross section of the display device, while the definition of the width Wₚ based on the light emitting diode GLED or the light emitting diode BLED is the same. In addition, if the display device is a quantum dot (QD) display device, the width Wₚ is defined as the distance from the center of the BLED to the center of the third adjacent BLED.

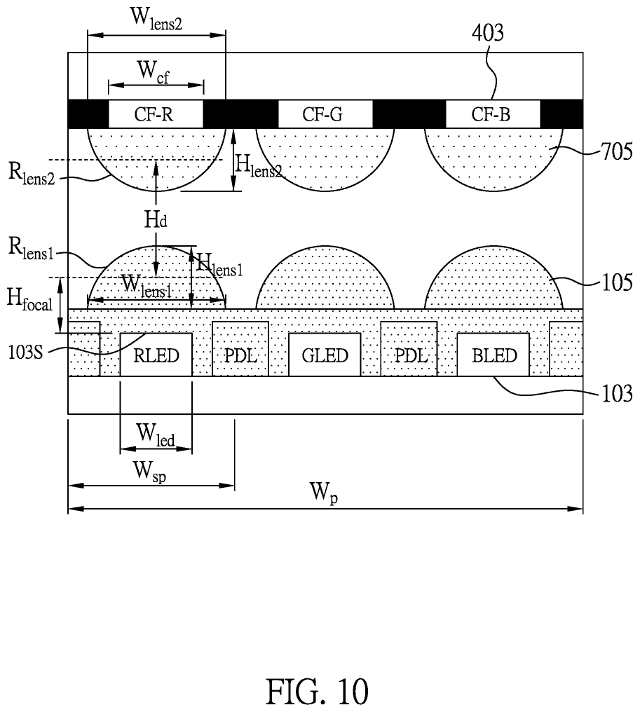

Moreover, in order to further illustrate the configuration for achieving high light emitting efficiency, please refer to FIG. 10, which illustrates the configuration relationship of the micro lens unit by taking the display device of FIG. 7 as an example. In FIG. 10, various components of the display pixel of the display device need to satisfy the following relationship:

$${W}_{sp} \geq {W}_{lens 1} \geq {W}_{cf} \geq {W}_{led} ;$$

$${W}_{lens 1} \geq {W}_{lens 2} ;$$

$${H}_{lens 1} \leq 1 / 2 {W}_{lens 1} ;$$

$${H}_{lens 2} \leq 1 / 2 {W}_{lens 2} ;$$

$$1 / 3 {W}_{p} = {W}_{sp} ;$$

$$and$$

$${H}_{focal} \leq ( 3 {R}_{lens 2} \times ( 3 {R}_{lens 1} - {H}_{d} ) ) \div ( {H}_{d} - ( 3 {R}_{lens 1} + 3 {R}_{lens 2} ) ) , \text{} 3 {R}_{lens 1} < {H}_{d} < ( 3 {R}_{lens 1} + 3 {R}_{lens 2} ) ,$$

where Wₚ represents the width of the display pixel, Wₛₚ represents the width of the sub-pixel, Wₗₑₙₛ₁ represents the width of the first micro lens unit 105, Hₗₑₙₛ₁ represents the height of the first micro lens unit 105, and Rₗₑₙₛ₁ represents the curvature radius of the first micro lens unit 105, Wₗₑₙₛ₂ represents the width of the second micro lens unit 705, Hₗₑₙₛ₂ represents the height of the second micro lens unit 705, Rₗₑₙₛ₂ represents the curvature radius of the second micro lens unit 705, W_{cf} represents the width of the color filter unit 403, W_{led} represents the width of the light emitting unit 103, H_{focal} represents the distance from the light emitting surface 103S of the light emitting unit 103 to the position of half the height of the first micro lens unit 105, and H_{d} represents the distance between the position of half the height of the first micro lens unit 105 and the position of half the height of the second micro lens unit 705.

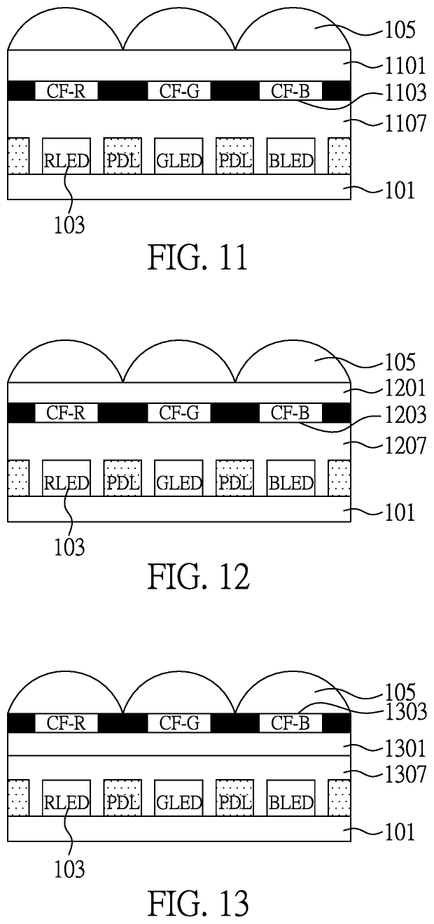

FIG. 11 is a schematic diagram of a display device according to an embodiment of the present disclosure. The display device of this embodiment is similar to the embodiment of FIG. 2, except that it further includes at least one color filter unit 1103, a second substrate 1101 and a resin layer 1107 between the first micro lens unit 105 and the light emitting unit 103. That is, in this embodiment, the at least one color filter unit 1103 is disposed between the first micro lens unit 105 and the light emitting unit 103 and, correspondingly, the at least one color filter unit 1103 includes a red filter unit CF-R, a green filter unit CF-G and a blue filter unit CF-B respectively corresponding to the red light emitting diode RLED, the green light emitting diode GLED and the blue light emitting diode BLED, but this is just for illustrative purpose and the present disclosure is not limited thereto. Moreover, the arc surface of the first micro lens unit 105 is an outwardly convex arc surface facing away from the color filter unit 1103, the second substrate 1101 is disposed between the first micro lens unit 105 and the color filter unit 1103, and the resin layer 1107 is disposed between the color filter unit 1103 and the first substrate 101.

FIG. 12 is a schematic diagram of a display device according to an embodiment of the present disclosure. The display device of this embodiment is similar to the embodiment of FIG. 2, except that it further includes at least one color filter unit 1203, a base material 1201 and a resin layer 1207 between the first micro lens unit 105 and the light emitting unit 103. That is, in this embodiment, the at least one color filter unit 1203 is disposed between the first micro lens unit 105 and the light emitting unit 103 and, correspondingly, the at least one color filter unit 1203 includes a red filter unit CF-R, a green filter unit CF-G and a blue filter unit CF-B, respectively corresponding to the red light emitting diode RLED, green light emitting diode GLED and the blue light emitting diode BLED, but this is just for illustrative purpose and the present disclosure is not limited thereto. Moreover, the arc surface of the first micro lens unit 105 is an outwardly convex arc surface facing away from the color filter unit 1203, the base material 1201 is arranged between the first micro lens unit 105 and the color filter unit 1203, the resin layer 1207 is disposed between the color filter unit 1203 and the light emitting unit 103, and the base material 1201 and the resin layer 1207 are made of the same material.

FIG. 13 is a schematic diagram of a display device according to an embodiment of the present disclosure. The display device of this embodiment is similar to the embodiment of FIG. 2, except that it further includes at least one color filter unit 1303, a second base material 1301 and a resin layer 1307 between the first micro lens unit 105 and the light emitting unit 103. That is, in this embodiment, the at least one color filter unit 1303 is arranged between the first micro lens unit 105 and the light emitting unit 103, and the first micro lens unit 105 is directly arranged on the color filter unit 1303. Correspondingly, the at least one color filter unit 1303 includes a red filter unit CF-R, a green filter unit CF-G and a blue filter unit CF-B respectively corresponding to the red light emitting diode RLED, the green light emitting diode GLED and the blue light emitting diode BLED, but this is just for illustrative purpose and the present disclosure is not limited thereto. Moreover, the arc surface of the first micro lens unit 105 is an outward convex arc surface facing away from the color filter unit 1303, the second base material 1301 is disposed between the color filter unit 1103 and the resin layer 1307, the thickness of the second base material 1301 is smaller than 100 micrometers (μm), and the resin layer 1307 is disposed on the light emitting unit 103.

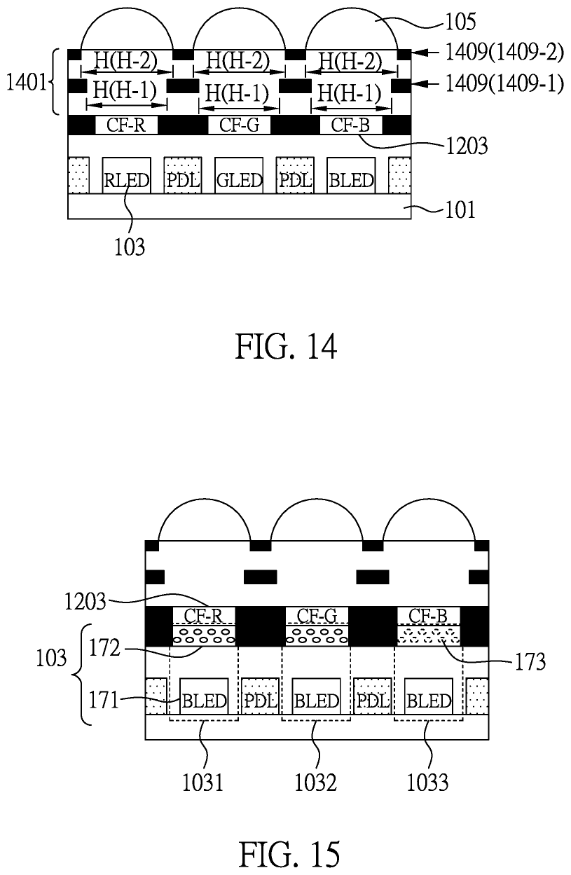

FIG. 14 is a schematic diagram of a display device according to an embodiment of the present disclosure. The display device of this embodiment is similar to the embodiment of FIG. 12, except that it further includes a collimation structure 1401 to substitute for the base material 1021 of FIG. 12, so that the collimation structure 1401 is disposed between the color filter unit 1203 and the first micro lens unit 105. The collimation structure 1401 includes a plurality of black matrix layers 1409 and, in FIG. 14, there are two black matrix layers 1409 provided as an example, wherein each of the black matrix layers 1409 has an opening H corresponding to the light emitting unit 103. One black matrix layer 1409-1 of the black matrix layers 1409 is closer to the light emitting unit 103 than the other black matrix layer 1409-2 of the black matrix layers 1409, and the width of the opening H-1 in the black matrix layer 1409-1 is smaller than the width of the opening H-2 in the black matrix layer 1409-2, wherein the width of the opening is the width of its bottom.

FIG. 15 is a schematic diagram of a display device according to an embodiment of the present disclosure. The display device of this embodiment is similar to the embodiment of FIG. 14, except that each of the at least one light emitting unit 103 includes a light source 171, and a light conversion component 172 or a light diffusion component 173. The light conversion component 172 or the light diffusion component 173 is disposed on the light source 171, and the color filter unit 1203 is disposed on the light conversion component 172 or the light diffusion component 173. In this embodiment, in more detail, the at least one light emitting unit 103 includes a light emitting unit 1031, a light emitting unit 1032, and a light emitting unit 1033. The light emitting unit 1031 corresponds to the red filter unit CF-R, its light source 171 is a blue light emitting diode BLED, and its light conversion component 172 is a red quantum dot. The light emitting unit 1032 corresponds to the green filter unit CF-G, its light source 171 is a blue light emitting diode BLED, and its light conversion component 172 is a green quantum dot. The light emitting unit 1033 corresponds to the blue filter unit CF-B, its light source 171 is a blue light emitting diode BLED, and its light diffusion component 173 is a transparent filling material containing diffusion particles, wherein the material of the diffusion particles may be, for example, TiO2. As a result, the light emitting unit 1031, the light emitting unit 1032 and the light emitting unit 1033 may respectively emit red light, green light and blue light for display.

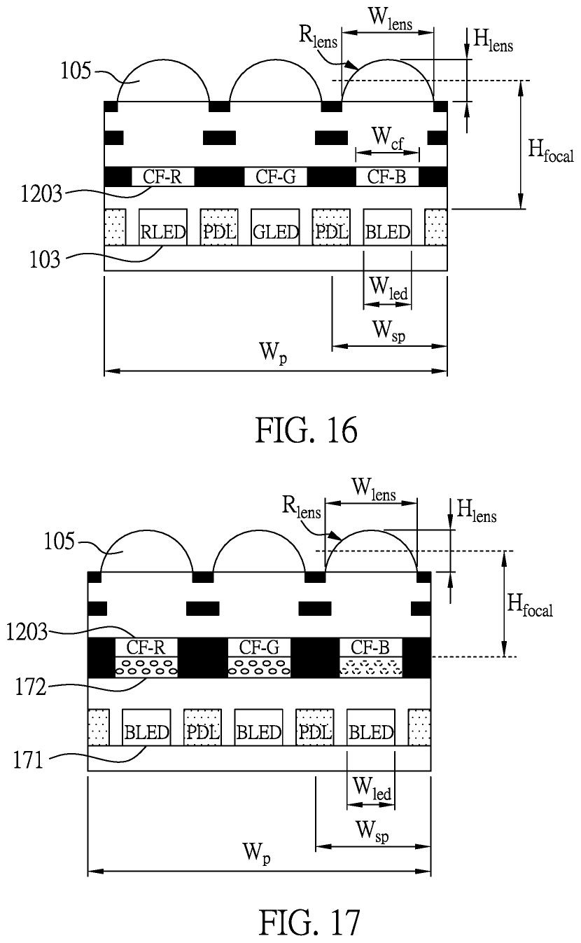

FIG. 16 shows the configuration relationship of the first micro lens unit to improve the light emitting efficiency by taking the display device of FIG. 14 as an example. In FIG. 16, various components of the display pixel of the display device need to satisfy the following relationship:

$${W}_{sp} \geq {W}_{lens} ,$$

$${W}_{cf} \geq {W}_{led} ,$$

$${H}_{lens} \leq 1 / 2 {W}_{lens} ,$$

$${H}_{focal} \leq 3 {R}_{lens} ;$$

$$and$$

$$1 / 3 {W}_{p} = {W}_{sp} ,$$

where Wₛₚ represents the width of the sub-pixel, Wₗₑₙₛ represents the width of the first micro lens unit 105, Hₗₑₙₛ represents the height of the first micro lens unit 105, Rₗₑₙₛ represents the curvature radius of the first micro lens unit 105, and W_{cf} represents the width of the color filter unit 1203, W_{led} represents the width of the light emitting unit 103, and H_{focal} represents the distance from the light emitting surface 103S of the light emitting unit 103 to the position of half the height of the first micro lens unit 105.

FIG. 17 shows the configuration relationship of the first micro lens unit to improve the light emitting efficiency by taking the display device of FIG. 15 as an example. In FIG. 17, various components of the display pixel of the display device need to satisfy the following relationship:

$${W}_{sp} \geq {W}_{lens} ,$$

$${W}_{cf} \geq {W}_{led} ,$$

$${H}_{lens} \leq 1 / 2 {W}_{lens} ,$$

$${H}_{foca} 1 \leq 3 {R}_{lens} ;$$

$$and$$

$$1 / 3 {W}_{p} = {W}_{sp} ,$$

where Wₛₚ represents the width of the sub-pixel, Wₗₑₙₛ represents the width of the first micro lens unit 105, Hₗₑₙₛ represents the height of the first micro lens unit 105, Rₗₑₙₛ represents the curvature radius of the first micro lens unit 105, W_{cf} represents the width of the color filter unit 1203, W_{led} represents the width of the light emitting unit 103, H_{focal} represents the distance from the color filter unit 1203 to the position of half the height of the first micro lens unit 105.

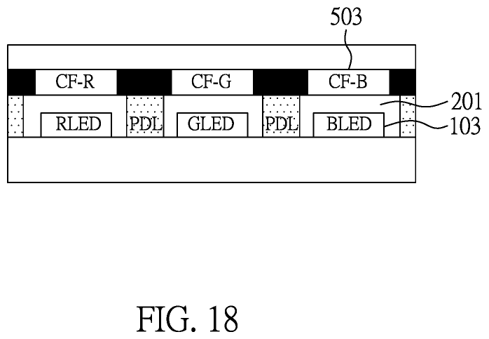

In addition, the present disclosure may also achieve high light emitting efficiency without using micro lenses. FIG. 18 is a schematic diagram of a display device according to an embodiment of the present disclosure. The display device of this embodiment is similar to the embodiment of FIG. 5, except that it does not have a first micro lens unit and there is at least one color filter unit 503 disposed on at least one light emitting unit 103. Therefore, the intermediary layer 201 is disposed between the color filter unit 503 and the light emitting unit 103, and surrounds the light emitting unit 103, wherein, in this embodiment, the material of the intermediary layer 201 is, for example, resin, and the material of the pixel define layer PDL between two adjacent light emitting units 105 is a highly reflective material, which may be a composite structure of white photoresist, gray photoresist or transparent photoresist and metal covering its sidewall so as to increase the light that is emitted by the light emitting unit 103 and passes through the color filter unit 503. In another embodiment, the pixel define layer may also be a black photoresist or other light-absorbing materials.

In view of the foregoing, it is known that, by adding micro lenses above the light emitting diodes of the display device, and configuring various components of the display pixel of the display device with a specific relationship, or using a highly reflective material as the material of the pixel define layer of the display device to increase the light emitted by the light emitting diode and passing through the color filter unit, the present disclosure is able to concentrate the large-angle light emitted by the light emitting diode, so as to limit the large-angle light within the critical angle of total reflection thereby improving the light emitting efficiency.

As long as the features of the various embodiments disclosed in the present disclosure do not violate the spirit of the disclosure or conflict with each other, they can be mixed and matched arbitrarily.

The aforementioned specific embodiments should be construed as merely illustrative, and not limiting the rest of the present disclosure in any way.

1. A display device, comprising:
a first substrate;
a light emitting unit arranged on the first substrate to provide a light; and
a first micro lens unit arranged on the light emitting unit to adjust a traveling direction of the light,
wherein the first micro lens unit has an arc surface, the first micro lens unit has a height, the arc surface has a curvature radius, there is a distance from a light emitting surface of the light emitting unit to a position of half the height of the first micro lens unit, and the distance and the curvature radius satisfy: 0.5H≤D≤3R1, where D represents the distance, H represents the height, and R1 represents the curvature radius.

2. The display device as claimed in claim 1, wherein the first micro lens unit has a width and a height, and the height is smaller than half of the width.

3. The display device as claimed in claim 1, wherein the first micro lens unit is disposed on the first substrate, and the arc surface is an outwardly convex arc surface facing away from the light emitting unit.

4. The display device as claimed in claim 1, further comprising a second substrate disposed opposite to the first substrate, wherein the first micro lens unit is disposed on the second substrate, and the arc surface is an outwardly convex arc surface facing the light emitting unit.

5. The display device as claimed in claim 1, further comprising an intermediary layer disposed between the first micro lens unit and the light emitting unit, wherein a refractive index of the intermediary layer is smaller than that of the first micro lens unit.

6. The display device as claimed in claim 1, wherein the light has a color of red or green.

7. The display device as claimed in claim 1, further comprising a second substrate and a color filter unit, wherein the color filter unit is disposed between the first micro lens unit and the second substrate.

8. The display device as claimed in claim 7, wherein the arc surface is an outwardly convex arc surface facing the color filter unit.

9. The display device as claimed in claim 7, wherein the arc surface is an outwardly convex arc surface facing the light emitting unit.

10. The display device as claimed in claim 7, further comprising a second micro lens unit disposed between the first micro lens unit and the color filter unit, wherein the arc surface of the first micro lens unit is an outwardly convex arc surface facing the color filter unit, the second micro lens unit has another arc surface which is an outwardly convex arc surface facing the light emitting unit, and a width of the first micro lens unit is greater than that of the second micro lens unit.

11. The display device as claimed in claim 5, further comprising a second substrate and a color filter unit, wherein the color filter unit is arranged between the first micro lens unit and the second substrate, and the arc surface of the first micro lens unit is an outwardly convex arc surface facing the color filter unit.

12. The display device as claimed in claim 11, further comprising a second micro lens unit disposed between the first micro lens unit and the color filter unit, wherein the arc surface of the first micro lens unit is an outwardly convex arc surface facing the color filter unit, the second micro lens unit has another arc surface which is an outwardly convex arc surface facing the light emitting unit, and a width of the first micro lens unit is larger than that of the second micro lens unit.

13. The display device as claimed in claim 1, further comprising a color filter unit, wherein the color filter unit is arranged between the first micro lens unit and the light emitting unit, and the arc surface of the first micro lens unit is an outwardly convex arc surface facing away from the color filter unit.

14. The display device as claimed in claim 13, further comprising a base material disposed between the first micro lens unit and the color filter unit, wherein a thickness of the base material is smaller than 100 μm.

15. The display device as claimed in claim 13, wherein the first micro lens unit is directly disposed on the color filter unit.

16. The display device as claimed in claim 13, further comprising a collimation structure disposed between the color filter unit and the first micro lens unit.

17. The display device as claimed in claim 16, wherein the collimation structure includes a plurality of black matrix layers, each having an opening corresponding to the light emitting unit.

18. The display device as claimed in claim 17, wherein one of the black matrix layers is closer to the light emitting unit than another one of the black matrix layers, and a width of the opening of the one of the black matrix layers is smaller than that of the opening of the another one of the black matrix layers.

19. The display device as claimed in claim 16, wherein the light emitting unit further comprises a light source and a light conversion component disposed on the light source.

20. A display device, comprising:
a first substrate;
a light emitting unit arranged on the first substrate to provide a light;
a color filter unit arranged on the light emitting unit; and
an intermediary layer arranged between the color filter unit and the light emitting unit and surrounding the light emitting unit,
wherein there is a pixel define layer between the light emitting unit and another adjacent light emitting unit, and a material of the pixel define layer is a highly reflective material.
